(19) United States
(12) Patent Application Publication
(10) Pub. No.: US 2025/0098375 A1
(43) Pub. Date: Mar. 20, 2025

(54) DISPLAY DEVICE

(71) Applicant: MAKITA CORPORATION, Anjo-shi (JP)

(72) Inventors: Takuma IWATANI, Anjo-shi (JP); Makoto CHIKARAISHI, Anjo-shi (JP)

(73) Assignee: MAKITA CORPORATION, Anjo-shi (JP)

(21) Appl. No.: 18/825,659

(22) Filed: Sep. 5, 2024

(30) Foreign Application Priority Data
Sep. 15, 2023 (JP) 2023-150391

(51) Int. Cl. H01L 33/48; B25F 5/02; B27B 17/00; B27B 17/02; H01L 33/58

(52) U.S. Cl. CPC H10H 20/8506; B25F 5/02; H10H 20/855; B27B 17/0008; B27B 17/02

(57) ABSTRACT

A display device may include: a first light emitting part that emits light; a second light emitting part that emits light; and a housing. The housing may include: a transmissive part defining an internal space in which the first and second light emitting parts are disposed, and that transmits light from the space of the housing to outside the housing; a partition wall part integrally formed with the transmissive part and partitioning the space of the housing into a first accommodating space where the first light emitting part is disposed and a second accommodating space where the second light emitting part is disposed; and a first shielding part disposed on a surface of the transmissive part, having a light transmittance smaller than a light transmittance of the transmissive part, and defining a first display element in the first accommodating space and a second display element in the second accommodating space.

### REFERENCE TO RELATED APPLICATIONS

This application claims priority to Japanese Patent Application No. 2023-150391, filed on Sep. 15, 2023, the entire contents of which are hereby incorporated by reference into the present application.

### TECHNICAL FIELD

The disclosure herein relates to a display device.

### BACKGROUND ART

European Patent Application Publication No. 3865250 describes a display device. The display device includes a first light emitting part configured to emit light, a second light emitting part configured to emit light, and a housing. The housing comprises a transmissive part defining an internal space in which the first light emitting part and the second light emitting part are disposed, and configured to transmit light from the internal space of the housing to outside of the housing, a partition wall part partitioning the internal space of the housing into a first accommodating space in which the first light emitting part is disposed and a second accommodating space in which the second light emitting part is disposed, and a first shielding part disposed on a surface of the transmissive part, having a light transmittance smaller than a light transmittance of the transmissive part, and defining a display element.

### SUMMARY

In the above display device, the transmissive part and the partition wall part are separate from each other. Due to this, a number of components of the display device is increased. The present teachings are aimed at providing an art that allows to reduce the number of components of a display device.

A display device disclosed herein may comprise: a first light emitting part configured to emit light; a second light emitting part configured to emit light; and a housing. The housing may comprise: a transmissive part defining an internal space in which the first light emitting part and the second light emitting part are disposed, and configured to transmit light from the internal space of the housing to outside of the housing; a partition wall part integrally formed with the transmissive part and partitioning the internal space of the housing into a first accommodating space in which the first light emitting part is disposed and a second accommodating space in which the second light emitting part is disposed; and a first shielding part disposed on a surface of the transmissive part, having a light transmittance smaller than a light transmittance of the transmissive part, and defining a first display element disposed in the first accommodating space and a second display element disposed in the second accommodating space.

According to the above configuration, the partition wall part is formed integrally with the transmissive part. Due to this, the number of components of the display device can be reduced.

### BRIEF DESCRIPTION OF DRAWINGS

FIG. 1 illustrates a perspective view of a working machine 2 according to a first embodiment.

FIG. 2 illustrates a perspective view of a display device 16 according to the first embodiment.

FIG. 3 illustrates a cross-sectional view of the display device 16 according to the first embodiment.

FIG. 4 illustrates a partial enlarged view of a first accommodating part 42 in the display device 16 according to the first embodiment.

FIG. 5 illustrates a cross-sectional view of a transmissive part 52, a partition wall part 54, and a sidewall part 94 according to the first embodiment.

FIG. 6 illustrates a cross-sectional view of the transmissive part 52, the partition wall part 54, the sidewall part 94, a first shielding part 56, and a second shielding part 58 before a first display element 82 and a second display element 84 are formed in the first embodiment.

FIG. 7 illustrates a cross-sectional view of the transmissive part 52, the partition wall part 54, the sidewall part 94, the first shielding part 56, and the second shielding part 58 after the first display element 82 and the second display element 84 have been formed in the first embodiment.

FIG. 8 illustrates an enlarged cross-sectional view of a first accommodating part 42 in a display device 16 according to a second embodiment.

FIG. 9 illustrates an enlarged cross-sectional view of a first accommodating part 42 in a display device 16 according to a third embodiment.

FIG. 10 illustrates an enlarged cross-sectional view of a first accommodating part 42 in a display device 16 according to a fourth embodiment.

### DESCRIPTION

Representative, non-limiting examples of the present disclosure will now be described in further detail with reference to the attached drawings. This detailed description is merely intended to teach a person of skill in the art further details for practicing preferred aspects of the present teachings and is not intended to limit the scope of the present disclosure. Furthermore, each of the additional features and teachings disclosed below may be utilized separately or in conjunction with other features and teachings to provide improved display devices, as well as methods for using and manufacturing the same.

Moreover, combinations of features and steps disclosed in the following detailed description may not be necessary to practice the present disclosure in the broadest sense, and are instead taught merely to particularly describe representative examples of the present disclosure. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

In one or more embodiments, an inner surface of the transmissive part may define the internal space. The first shielding part may be disposed on the inner surface of the transmissive part.

In a configuration where the first shielding part is disposed on an outer surface of the transmissive part, if the display device touches a user, for example, a scar may be formed on the first shielding part. According to the above configuration, since the first shielding part is disposed on the inner surface of the transmissive part, the first shielding part can be suppressed from being damaged with a scar.

In one or more embodiments, the housing may further comprise a first diffusion part disposed on the first shielding part and configured to diffuse light.

According to the above configuration, the light is diffused by the first diffusion part, and also passes through the first display element and the second display element. Due to this, even when the display device is tilted, the user can visually recognize the first display element and the second display element.

In one or more embodiments, a material of the transmissive part may be same as a material of the partition wall part. The housing further may comprise a second shielding part disposed on the partition wall part and having a light transmittance smaller than the light transmittance of the transmissive part.

According to the above configuration, the light emitted by the first light emitting part can be suppressed from passing through the second display element via the partition wall part, and also the light emitted by the second light emitting part can be suppressed from passing through the first display element via the partition wall part.

In one or more embodiments, a material of the second shielding part may be same as a material of the first shielding part.

According to the above configuration, the display device can be easily manufactured.

In one or more embodiments, the display device may further comprise a circuit board on which the first light emitting part and the second light emitting part are mounted, the circuit board being fixed to the housing. The circuit board may be in contact with a contacting region of the partition wall part. The second shielding part may be not disposed on the contacting region.

Tiny bumps and dips may be formed on the second shielding part on the partition wall part. In a configuration where the second shielding part is disposed in the contacting region, the circuit board may contact the tiny bumps and dips on the second shielding part and thus the circuit board may not be stably fixed to the housing. According to the above configuration, the circuit board can be stably fixed to the housing.

In one or more embodiments, the housing may further comprise: a first diffusion part disposed on the first shielding part and configured to diffuse light; and a second diffusion part disposed on the second shielding part and configured to diffuse light.

According to the above configuration, a part of the light emitted by the first light emitting part hits the second diffusion part, and is diffused toward the first display element. Due to this, visibility of the first display element can be improved. A part of the light emitted by the second light emitting part hits the second diffusion part, and is diffused toward the second display element. Due to this, visibility of the second display element can be improved.

In one or more embodiments, a material of the first diffusion part may be same as a material of the second diffusion part.

According to the above configuration, the display device can be easily manufactured.

In one or more embodiments, the transmissive part may define an outer shape of the housing.

According to the configuration, the configuration of the housing can be simplified.

In one or more embodiments, the light transmittance of the transmissive part may be equal to or more than 5% and equal to or less than 80%.

According to the above configuration, the first display element and second display element can be suppressed from being visually recognized when both the first and second light emitting parts are not emitting light.

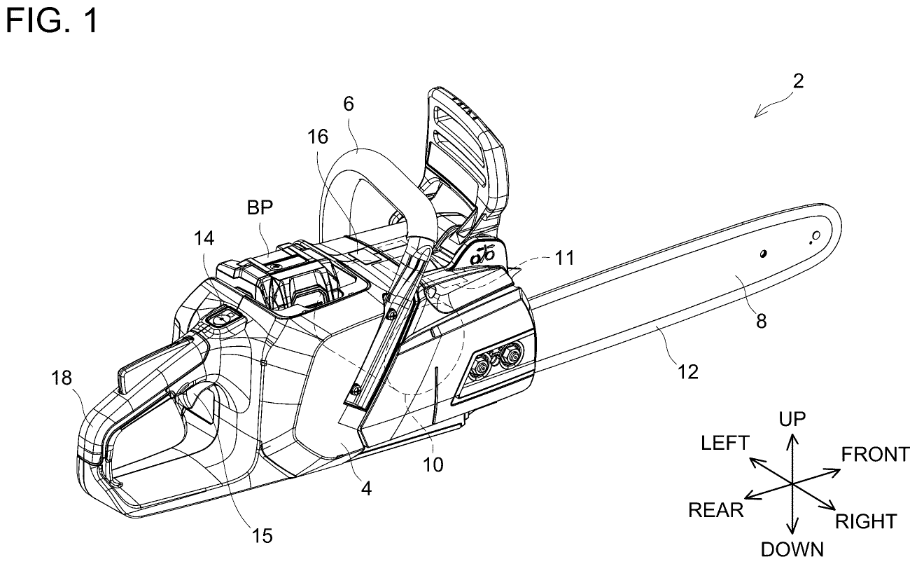

(First Embodiment) As illustrated in FIG. 1, a working machine 2 is for example a hand-held chainsaw. The working machine 2 comprises a body housing 4, a front handle 6, a guide bar 8, a motor 10, a control unit 11, a saw chain 12, a main power switch 14, a trigger 15, and a display device 16. The body housing 4 comprises a rear handle 18 positioned at its rear portion. Hereafter, when the working machine 2 is placed on a plane such as a ground, a direction perpendicular to the plane will be referred to as an up-down direction, a direction in which a longitudinal direction of the guide bar 8 is projected onto the plane will be referred to as a front-rear direction, and a direction perpendicular to the up-down and front-rear directions will be referred to as a left-right direction.

The front handle 6 is fixed to the body housing 4. The front handle 6 extends up-frontward from a right surface of the body housing 4 and then bends to extend leftward, and further bends to extend downward. A user grips the front handle 6 with one hand and grips the rear handle 18 with another hand during work by the working machine 2.

The guide bar 8 has an elongate plate shape. The guide bar 8 is fixed to the body housing 4 so as to protrude frontward from the body housing 4.

The motor 10 is disposed within the body housing 4. The motor 10 is for example a brushless motor. The motor 10 is configured to operate with power supplied from a battery pack BP. The battery pack BP is detachably attached to the body housing 4.

The control unit 11 is disposed within the body housing 4. The control unit 11 controls the motor 10.

The saw chain 12 is attached to the guide bar 8 along a periphery of the guide bar 8. The saw chain 12 operates by rotating along the periphery of the guide bar 8 when the motor 10 rotates. Due to this, a cutting object such as wood is cut.

The main power switch 14 is disposed on the rear handle 18. The main power switch 14 is configured to switch between an ON state and an OFF state according to a user's operation. When the main power switch 14 is in the ON state, power from the battery pack BP can be supplied to the motor 10. When the main power switch 14 is in the OFF state, the power from the battery pack BP cannot be supplied to the motor 10.

The trigger 15 is mounted such that the trigger 15 can be pressed into the rear handle 18. When the trigger 15 is pressed in with the main power switch 14 in the ON state, the motor 10 rotates.

The display device 16 is disposed on an upper surface of the body housing 4. The display device 16 is disposed on a front side of the battery pack BP. The display device 16 is disposed near the front handle 6. The display device 16 is visually recognized by the user when the user is grasping the front handle 6 and the rear handle 18. In a modification, the display device 16 is disposed parallel to a line connecting an upper end of the front handle 6 and an upper end of the rear handle 18 and also disposed inclined relative to a plane when the working machine 2 is placed on the plane such as a ground. Due to this, visibility of the display device 16 for the user can be improved.

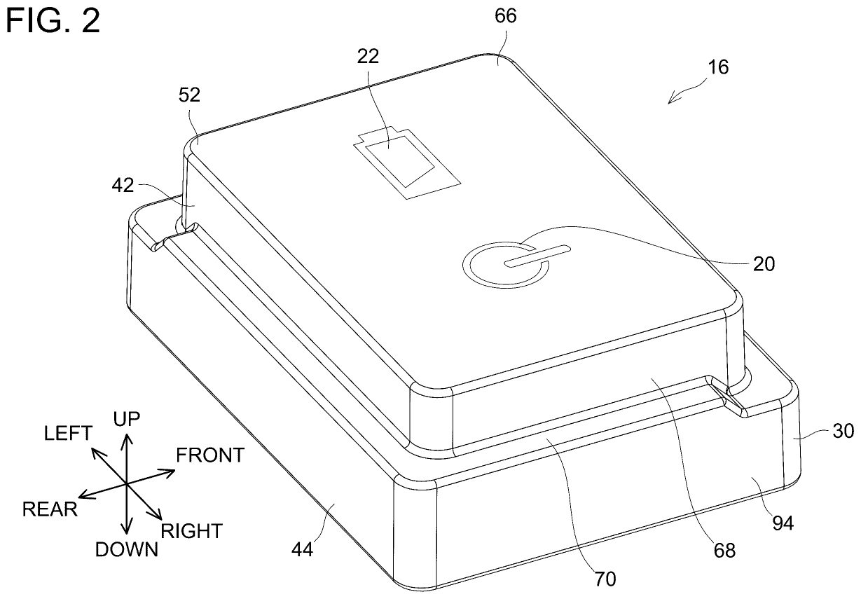

As illustrated in FIG. 2, the display device 16 displays states of the working machine 2. The display device 16 displays, for example, an ON indication 20 indicative of the main power switch 14 (see FIG. 1) being in the ON state and a battery level indication 22 indicative of a remaining level of charge in the battery pack BP (see FIG. 1) being equal to or less than a predetermined value.

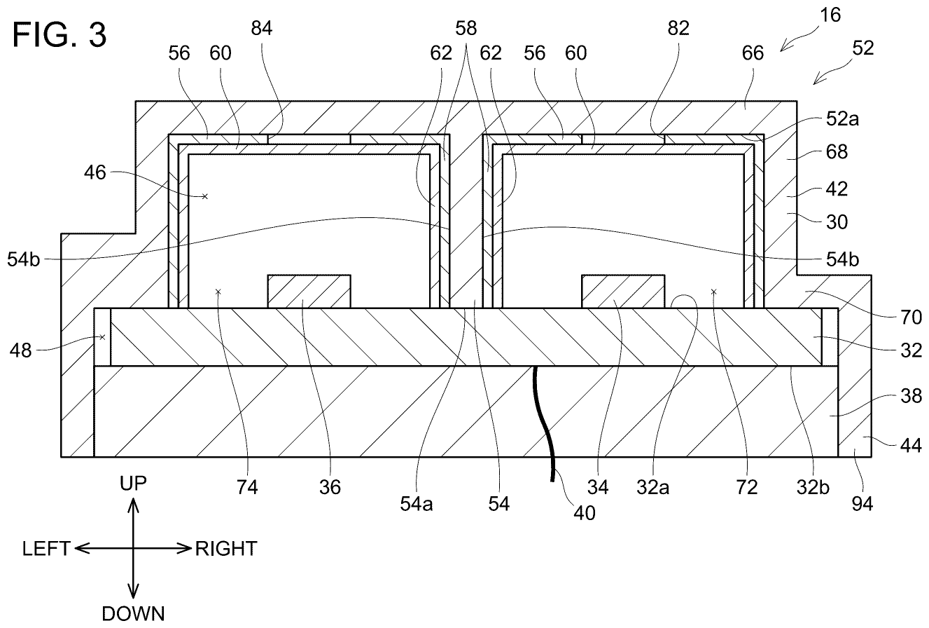

As illustrated in FIG. 3, the display device 16 comprises a housing 30, a circuit board 32, a first light emitting part 34, a second light emitting part 36, adhesive 38, and a lead wire 40. The housing 30 defines an outer shape of the display device 16. A part of the housing 30 is exposed to outside of the working machine 2 (see FIG. 1). The housing 30 comprises a first accommodating part 42 and a second accommodating part 44. The first accommodating part 42 defines an outer shape of an upper portion of the housing 30. The first accommodating part 42 defines a first internal space 46 in its inside. The second accommodating part 44 defines an outer shape of a lower portion of the housing 30. The second accommodating part 44 defines a second internal space 48 in its inside.

The circuit board 32 is disposed in the second internal space 48. The circuit board 32 has a plate shape. An upper surface 32a of the circuit board 32 is in contact with the first accommodating part 42 from below.

The first light emitting part 34 and the second light emitting part 36 are mounted on the upper surface 32a of the circuit board 32. The first light emitting part 34 and the second light emitting part 36 are disposed in the first internal space 46. The first light emitting part 34 and the second light emitting part 36 are for example LED elements. The first light emitting part 34 and the second light emitting part 36 are controlled by the control unit 11 (see FIG. 1). The first light emitting part 34 and the second light emitting part 36 are configured to emit light with power from the battery pack BP (see FIG. 1). The first light emitting part 34 emits light when the main power switch 14 (see FIG. 1) is in the ON state. The second light emitting part 36 emits light when the remaining level of the charge in the battery pack BP (see FIG. 1) is equal to or less than the predetermined value.

The adhesive 38 is disposed in the second internal space 48. The adhesive 38 is in contact with a lower surface 32b of the circuit board 32. The lower surface 32b is opposite from the upper surface 32a. The adhesive 38 is injected into the second internal space 48 and then cured with the upper surface 32a of the circuit board 32 being in contact with the first accommodating part 42 from below, by which the circuit board 32 is fixed to the housing 30.

The lead wire 40 is connected to the lower surface 32b of the circuit board 32. The lead wire 40 passes through the adhesive 38, and extends from the second internal space 48 to outside of the housing 30. The lead wire 40 is connected to the control unit 11 (see FIG. 1).

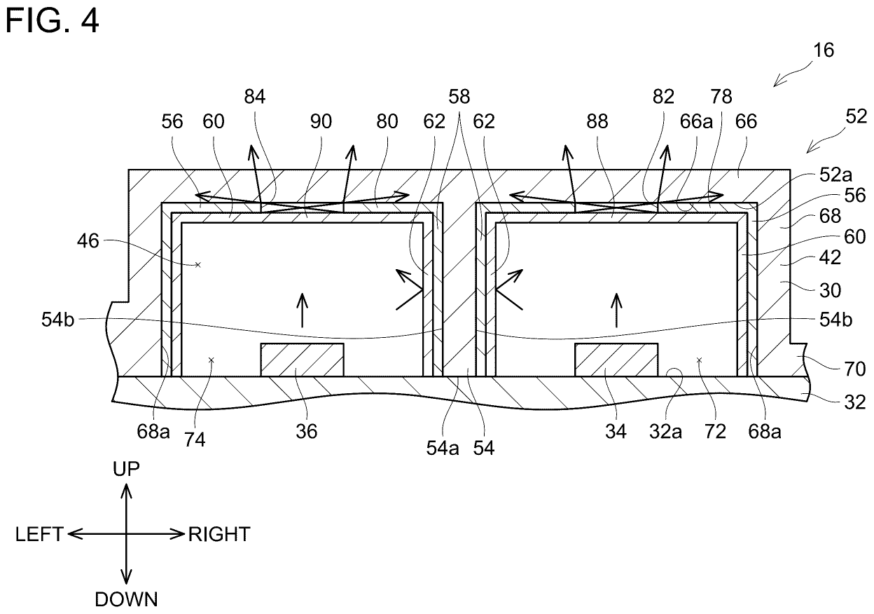

As illustrated in FIG. 4, the first accommodating part 42 comprises a transmissive part 52, a partition wall part 54, a first shielding part 56, a second shielding part 58, a first diffusion part 60, and a second diffusion part 62.

The transmissive part 52 defines an outer shape of the first accommodating part 42. A part of the transmissive part 52 is exposed outside the working machine 2 (see FIG. 1). An inner surface 52a of the transmissive part 52 defines the first internal space 46. The transmissive part 52 is configured to transmit light. The transmissive part 52 is constituted of a light transmissive material. The light transmissive material is for example acrylic, polycarbonate, polyamide, and/or ABS. A light transmittance of the transmissive part 52 is equal to or more than 5% and equal to or less than 80%. The light transmittance of the transmissive part 52 may be equal to or more than 5% and equal to or less than 50%, may be equal to or more than 10% and equal to or less than 35%, and may be equal to or more than 10% and equal to or less than 20%.

The transmissive part 52 comprises an upper wall part 66, a sidewall part 68, and a lower wall part 70. The upper wall part 66 is exposed outside the working machine 2 (see FIG. 1). The upper wall part 66 has a rectangular wall shape. The sidewall part 68 is disposed over an entirety of a periphery of the upper wall part 66. The sidewall part 68 extends downward from the periphery of the upper wall part 66. The sidewall part 68 surrounds the first light emitting part 34 and the second light emitting part 36. The lower wall part 70 is disposed at a lower portion of an outer side surface of the sidewall part 68. The lower wall part 70 extends from the outer side surface of the sidewall part 68 outward of the sidewall part 68 along a plane including the front-rear direction and the left-right direction. The sidewall part 68 and the lower wall part 70 are in contact with the upper surface 32a of the circuit board 32.

The partition wall part 54 is disposed in the first internal space 46. The partition wall part 54 is configured to transmit light. A material of the partition wall part 54 is the same as a material of the transmissive part 52. The partition wall part 54 is disposed between the first light emitting part 34 and the second light emitting part 36. The partition wall part 54 divides the first internal space 46 into a first accommodating space 72 and a second accommodating space 74. The first light emitting part 34 is disposed in the first accommodating space 72. The second light emitting part 36 is disposed in the second accommodating space 74.

The partition wall part 54 is formed integrally with the upper wall part 66. The partition wall part 54 extends downward from an inner surface 66a of the upper wall part 66 toward the upper surface 32a of the circuit board 32. A lower surface 54a of the partition wall part 54 makes surface contact with the upper surface 32a of the circuit board 32. The lower surface 54a of the partition wall part 54 corresponds to a contacting region of the circuit board 32.

The first shielding part 56 is disposed on the inner surface 66a of the upper wall part 66 and an inner surface 68a of the sidewall part 68. Each of the inner surface 66a of the upper wall part 66 and the inner surface 68a of the sidewall part 68 is a part of the inner surface 52a of the transmissive part 52. The first shielding part 56 is configured not to transmit light. A light transmittance of the first shielding part 56 is smaller than the light transmittance of the transmissive part 52. The light transmittance of the first shielding part 56 is equal to or less than 1%. The first shielding part 56 is constituted of a light non-transmissive material. The first shielding part 56 is constituted of a black material. The first shielding part 56 is for example constituted of acrylic paint. The first shielding part 56 is constituted of a coating film. A thickness of the first shielding part 56 is equal to or more than 1 μm and equal to or less than 50 μm. Due to this, a coating amount of the first shielding part 56 is decreased, and also light transmission through the first shielding part 56 can be suppressed. The thickness of the first shielding part 56 may be equal to or more than 3 μm and equal to or less than 30 μm, and may be equal to or more than 5 μm and equal to or less than 20 μm.

The first shielding part 56 comprises a first right shielding part 78 and a first left shielding part 80. The first right shielding part 78 is disposed in the first accommodating space 72. The first display element 82 is defined in the first right shielding part 78. The first display element 82 is disposed on the inner surface 66a of the upper wall part 66. The first display element 82 is formed by, for example, a part of the first right shielding part 78 being removed by laser. Due to this, light can pass through the first display element 82. The first display element 82 has a shape which defines an outer shape of the ON indication 20 (see FIG. 2). When the first light emitting part 34 emits light, the light passes through the first display element 82, by which the ON indication 20 is displayed on the display device 16.

The first left shielding part 80 is disposed in the second accommodating space 74. The second display element 84 is defined in the first left shielding part 80. The second display element 84 is disposed on the inner surface 66a of the upper wall part 66. The second display element 84 is formed by, for example, a part of the first left shielding part 80 being removed by laser. Due to this, light can pass through the second display element 84. The second display element 84 has a shape which defines an outer shape of the battery level indication 22 (see FIG. 2). When the second light emitting part 36 emits light, the light passes through the second display element 84, by which the battery level indication 22 is displayed on the display device 16.

The second shielding part 58 is disposed on a side surface 54b of the partition wall part 54. The second shielding part 58 is not disposed on the lower surface 54a of the partition wall part 54. The second shielding part 58 is disposed in each of the first accommodating space 72 and the second accommodating space 74.

The second shielding part 58 is configured not to transmit light. A material of the second shielding part 58 is the same as the material of the first shielding part 56. The second shielding part 58 is constituted of a coating film. A thickness of the second shielding part 58 is substantially equal to the thickness of the first shielding part 56.

The first diffusion part 60 is disposed on the first shielding part 56. The first shielding part 56 is interposed between the inner surface 66a of the upper wall part 66 and the first diffusion part 60 and between the inner surface 68a of the sidewall part 68 and the first diffusion part 60. The first diffusion part 60 is configured to diffuse light. The first diffusion part 60 is constituted of a light diffusive material. A light transmittance of the first diffusion part 60 is smaller than the light transmittance of the transmissive part 52. The first diffusion part 60 is constituted of a white material. The first diffusion part 60 is constituted of, for example, acrylic paint. The first diffusion part 60 is constituted of a coating film. A thickness of the first diffusion part 60 is equal to or more than 3 μm and equal to or less than 100 μm. Due to this, the light transmittance of the first diffusion part 60 is suppressed from lowering, and also the light is diffused. The thickness of the first diffusion part 60 may be equal to or more than 5 μm and equal to or less than 50 μm and may be equal to or more than 10 μm and equal to or less than 30 μm.

The first diffusion part 60 comprises a first right diffusion part 88 and a first left diffusion part 90. The first right diffusion part 88 is disposed in the first accommodating space 72. The first right diffusion part 88 is disposed on the first right shielding part 78. The first right shielding part 78 is interposed between the first right diffusion part 88 and the transmissive part 52. The first right diffusion part 88 is disposed between the first right shielding part 78 and the first light emitting part 34. The first right diffusion part 88 covers the first display element 82. Light diffused by the first right diffusion part 88 passes through the first display element 82. Due to this, even if the user tilts the display device 16, he/she can visually recognize the ON indication 20 (see FIG. 2). In FIG. 4, the light is shown by arrows.

The first left diffusion part 90 is disposed in the second accommodating space 74. The first left diffusion part 90 is disposed on the first left shielding part 80. The first left shielding part 80 is interposed between the first left diffusion part 90 and the transmissive part 52. The first left diffusion part 90 is interposed between the first left shielding part 80 and the second light emitting part 36. The first left diffusion part 90 covers the second display element 84. Light diffused by the first left diffusion part 90 passes through the second display element 84. Due to this, even if the user tilts the display device 16, he/she can visually recognize the battery level indication 22 (see FIG. 2).

The second diffusion part 62 is disposed on the second shielding part 58. The second shielding part 58 is interposed between the side surface 54b of the partition wall part 54 and the second diffusion part 62. The second diffusion part 62 is not disposed on the lower surface 54a of the partition wall part 54. The second diffusion part 62 is disposed in each of the first accommodating space 72 and the second accommodating space 74.

The second diffusion part 62 is configured to diffuse light. A material of the second diffusion part 62 is the same as the material of the first diffusion part 60. The second diffusion part 62 is constituted of a coating film. A thickness of the second diffusion part 62 is substantially equal to the thickness of the first diffusion part 60.

As illustrated in FIG. 3, the second accommodating part 44 comprises a sidewall part 94. The sidewall part 94 is disposed at an entirety of a periphery of the lower wall part 70 of the transmissive part 52. The sidewall part 94 extends downward from the periphery of the lower wall part 70. The sidewall part 94 is formed integrally with the transmissive part 52. The sidewall part 94 is configured to transmit light. The sidewall part 94 is constituted of a light transmissive material. A material of the sidewall part 94 is the same as the material of the transmissive part 52. The housing 30 can be easily manufactured by forming the first accommodating part 42 and the second accommodating part 44 as one unit.

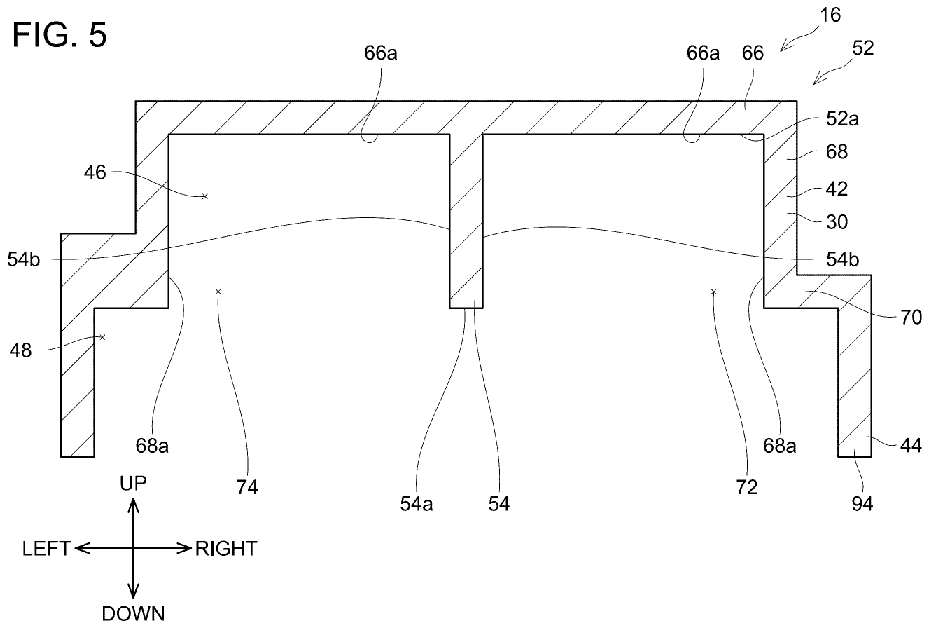

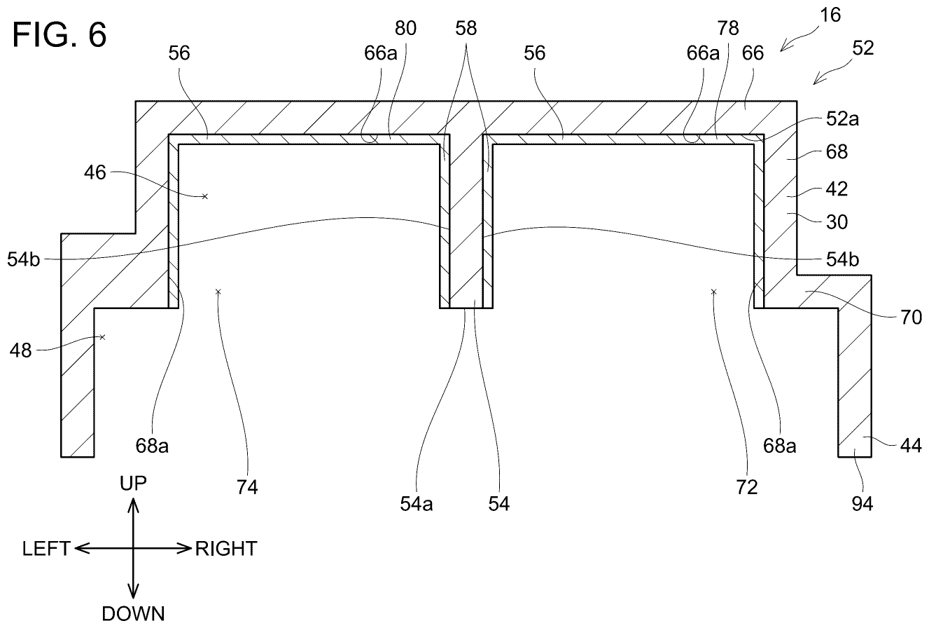

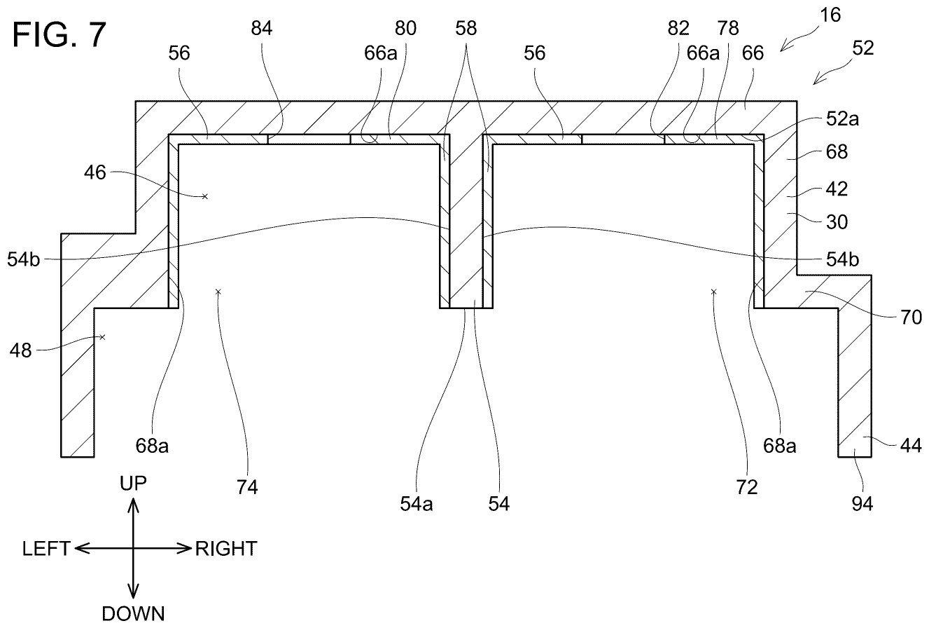

A method of manufacturing the housing 30 will be described. Firstly, as illustrated in FIG. 5, the transmissive part 52, the partition wall part 54, and the sidewall part 94 are manufactured by molding them as one unit. Next, as illustrated in FIG. 6, the first shielding part 56 is applied on the inner surface 66a of the upper wall part 66 and the inner surface 68a of the sidewall part 68. Further, the second shielding part 58 is applied on the side surface 54b of the partition wall part 54. Next, as illustrated in FIG. 7, a part of the first right shielding part 78 is removed by laser, by which the first display element 82 is formed in the first right shielding part 78. Also, a part of the first left shielding part 80 is removed by laser, by which the second display element 84 is formed in the first left shielding part 80. Lastly, as illustrated in FIG. 3, the first diffusion part 60 is applied on the first shielding part 56. Further, the second diffusion part 62 is applied on the second shielding part 58.

(Effects) The display device 16 according to the present embodiment comprises: the first light emitting part 34 configured to emit light; the second light emitting part 36 configured to emit light; and the housing 30. The housing 30 comprises: the transmissive part 52 defining the first internal space 46 (example for an internal space) in which the first light emitting part 34 and the second light emitting part 36 are disposed, and configured to transmit light from the first internal space 46 of the housing 30 to outside of the housing 30; the partition wall part 54 integrally formed with the transmissive part 52 and partitioning the first internal space 46 of the housing 30 into the first accommodating space 72 in which the first light emitting part 34 is disposed and the second accommodating space 74 in which the second light emitting part 36 is disposed; and the first shielding part 56 disposed on a surface of the transmissive part 52, having a light transmittance smaller than the light transmittance of the transmissive part 52, and defining the first display element 82 disposed in the first accommodating space 72 and the second display element 84 disposed in the second accommodating space 74.

According to the above configuration, the partition wall part 54 is formed integrally with the transmissive part 52. Due to this, the number of components of the display device 16 can be reduced.

The inner surface 52a of the transmissive part 52 defines the first internal space 46. The first shielding part 56 is disposed on the inner surface 52a of the transmissive part 52.

In a configuration where the first shielding part 56 is disposed on an outer surface of the transmissive part 52, if the display device 16 touches a user, for example, a scar may be formed on the first shielding part 56. According to the above configuration, since the first shielding part 56 is disposed on the inner surface 52a of the transmissive part 52, the first shielding part 56 can be suppressed from being damaged with a scar.

The housing 30 further comprises the first diffusion part 60 disposed on the first shielding part 56 and configured to diffuse light.

According to the above configuration, the light is diffused by the first diffusion part 60, and also passes through the first display element 82 and the second display element 84. Due to this, even when the display device 16 is tilted, the user can visually recognize the first display element 82 and the second display element 84.

The material of the transmissive part 52 is the same as the material of the partition wall part 54. The housing 30 further comprises the second shielding part 58 disposed on the partition wall part 54 and having a light transmittance smaller than the light transmittance of the transmissive part 52.

According to the above configuration, the light emitted by the first light emitting part 34 can be suppressed from passing through the second display element 84 via the partition wall part 54, and also the light emitted by the second light emitting part 36 can be suppressed from passing through the first display element 82 via the partition wall part 54.

The material of the second shielding part 58 is the same as the material of the first shielding part 56.

According to the above configuration, the display device 16 can be easily manufactured.

The display device 16 further comprises the circuit board 32 on which the first light emitting part 34 and the second light emitting part 36 are mounted, the circuit board 32 being fixed to the housing 30. The circuit board 32 is in contact with the lower surface 54a (an example for the contacting region) of the partition wall part 54. The second shielding part 58 is not disposed on the lower surface 54a.

Tiny bumps and dips may be formed on the second shielding part 58 on the partition wall part 54. In a configuration where the second shielding part 58 is disposed in the lower surface 54a, the circuit board 32 may contact the tiny bumps and dips on the second shielding part 58 and thus the circuit board 32 may not be stably fixed to the housing 30. According to the above configuration, the circuit board 32 can be stably fixed to the housing 30.

The housing 30 further comprises the first diffusion part 60 disposed on the first shielding part 56 and configured to diffuse light; and the second diffusion part 62 disposed on the second shielding part 58 and configured to diffuse light.

According to the above configuration, a part of the light emitted by the first light emitting part 34 hits the second diffusion part 62, and is diffused toward the first display element 82. Due to this, visibility of the first display element 82 can be improved. A part of the light emitted by the second light emitting part 36 hits the second diffusion part 62, and is diffused toward the second display element 84. Due to this, visibility of the second display element 84 can be improved.

The material of the first diffusion part 60 is the same as the material of the second diffusion part 62.

According to the above configuration, the display device 16 can be easily manufactured.

The transmissive part 52 defines the outer shape of the housing 30.

According to the above configuration, a configuration of the housing 30 can be simplified.

The light transmittance of the transmissive part 52 is equal to or more than 5% and equal to or less than 80%.

According to the above configuration, the first light emitting part 34 and the second light emitting part 36 can be suppressed from visually recognized when the first display element 82 and the second display element 84 are not emitting light.

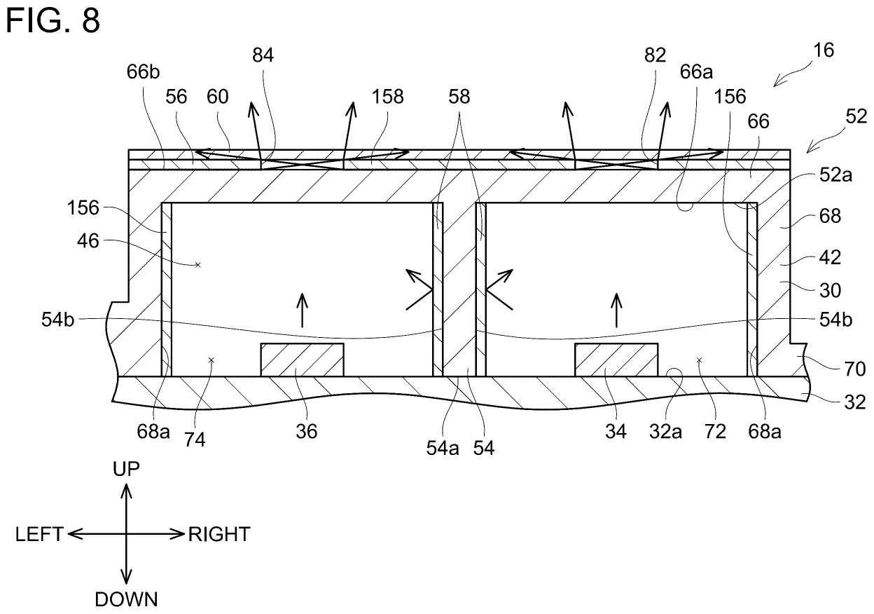

(Second Embodiment) In a second embodiment, points that differ from the first embodiment will be described. As illustrated in FIG. 8, the first shielding part 56 comprises a first inner shielding part 156 and a first outer shielding part 158.

The first inner shielding part 156 is disposed on the inner surface 68a of the sidewall part 68. The first inner shielding part 156 is disposed in each of the first accommodating space 72 and the second accommodating space 74.

The first outer shielding part 158 is disposed outside the housing 30. The first outer shielding part 158 is disposed on an outer surface 66b of the upper wall part 66. The outer surface 66b defines a part of the outer shape of the housing 30. The outer surface 66b is opposite from the inner surface 66a of the upper wall part 66.

The first outer shielding part 158 defines the first display element 82 and the second display element 84. The first display element 82 is disposed directly above the first light emitting part 34. The second display element 84 is disposed directly above the second light emitting part 36.

The housing 30 comprises only the first diffusion part 60, and does not comprise the second diffusion part 62 according to the first embodiment. The first diffusion part 60 is disposed outside the housing 30. The first diffusion part 60 is disposed on the first outer shielding part 158. The first outer shielding part 158 is interposed between the first diffusion part 60 and the outer surface 66b of the upper wall part 66.

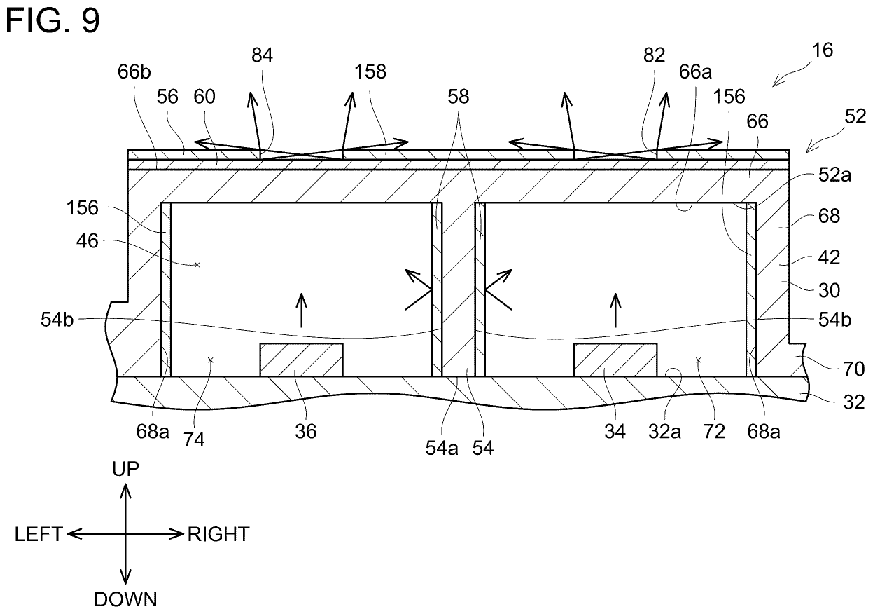

(Third Embodiment) In a third embodiment, points that differ from the second embodiment will be described. As illustrated in FIG. 9, the first diffusion part 60 is disposed on the outer surface 66b of the upper wall part 66. The first outer shielding part 158 is disposed on the first diffusion part 60. The first diffusion part 60 is interposed between the first outer shielding part 158 and the outer surface 66b of the upper wall part 66.

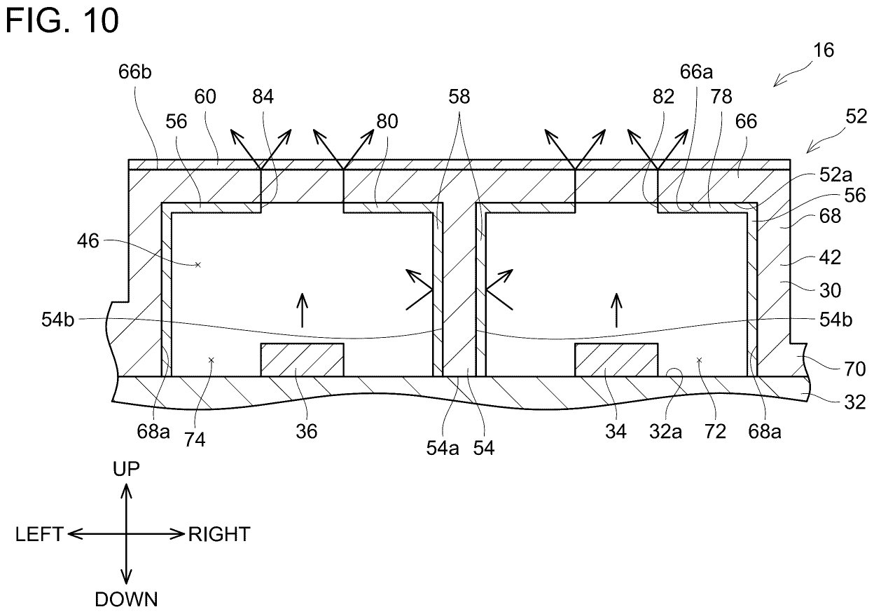

(Fourth Embodiment) In a fourth embodiment, points that differ from the first embodiment will be described. As illustrated in FIG. 10, the housing 30 comprises only the first diffusion part 60, and does not comprise the second diffusion part 62 according to the first embodiment. The first diffusion part 60 is disposed outside the housing 30. The first diffusion part 60 is disposed on the outer surface 66b of the upper wall part 66.

(Modifications) The working machine 2 according to an aspect may be a working machine other than a chain saw, and thus may be for example a grass cutter, a lawn mower, a hedge trimmer, a blower, a cart, a snow remover, or a tiller.

In the display device 16 according to an aspect, the number of indications displayed on the display device 16 may not be limited to two, i.e., the ON indication 20 and the battery level indication 22, but may be three or more. For example, the number of indications displayed on the display device 16 may be four, or six. In these cases, the display device 16 comprises a same number of light emitting parts and accommodating spaces as the number of indications displayed on the display device 16.

In the display device 16 according to an aspect, the first shielding part 56, the second shielding part 58, the first diffusion part 60, and the second diffusion part 62 may be formed by vapor deposition, may be formed by films, and/or may be formed by insert molding.

The display device 16 according to an aspect may not comprise the first diffusion part 60 and the second diffusion part 62.

In an aspect, the transmissive part 52 and the partition wall part 54 may be formed as a unit by integral molding with the same material. Alternatively, the transmissive part 52 and the partition wall part 54 may be separate members, and may be integrally formed by bonding them. In this case, the material of the transmissive part 52 may be the same as or differ from the material of the partition wall part 54.

The partition wall part 54 according to an aspect may be configured not to transmit light, but may be configured to diffuse light.

In an aspect, the material of the first shielding part 56 may differ from the material of the second shielding part 58.

In an aspect, the material of the first diffusion part 60 may differ from the material of the second diffusion part 62.

What is claimed is:

1. A display device comprising:
a first light emitting part configured to emit light;
a second light emitting part configured to emit light; and
a housing,
wherein the housing comprises:
a transmissive part defining an internal space in which the first light emitting part and the second light emitting part are disposed, and configured to transmit light from the internal space of the housing to outside of the housing;
a partition wall part integrally formed with the transmissive part and partitioning the internal space of the housing into a first accommodating space in which the first light emitting part is disposed and a second accommodating space in which the second light emitting part is disposed; and
a first shielding part disposed on a surface of the transmissive part, having a light transmittance smaller than a light transmittance of the transmissive part, and defining a first display element disposed in the first accommodating space and a second display element disposed in the second accommodating space.

2. The display device according to claim 1, wherein an inner surface of the transmissive part defines the internal space, and
the first shielding part is disposed on the inner surface of the transmissive part.

3. The display device according to claim 2, wherein the housing further comprises a first diffusion part disposed on the first shielding part and configured to diffuse light.

4. The display device according to claim 1, wherein a material of the transmissive part is same as a material of the partition wall part, and
the housing further comprises a second shielding part disposed on the partition wall part and having a light transmittance smaller than the light transmittance of the transmissive part.

5. The display device according to claim 4, wherein a material of the second shielding part is same as a material of the first shielding part.

6. The display device according to claim 4, further comprising a circuit board on which the first light emitting part and the second light emitting part are mounted, the circuit board being fixed to the housing,
wherein the circuit board is in contact with a contacting region of the partition wall part, and
the second shielding part is not disposed on the contacting region.

7. The display device according to claim 4, wherein the housing further comprises:
a first diffusion part disposed on the first shielding part and configured to diffuse light; and
a second diffusion part disposed on the second shielding part and configured to diffuse light.

8. The display device according to claim 7, wherein a material of the first diffusion part is same as a material of the second diffusion part.

9. The display device according to claim 1, wherein the transmissive part defines an outer shape of the housing.

10. The display device according to claim 1, wherein the light transmittance of the transmissive part is equal to or more than 5% and equal to or less than 80%.

11. The display device according to claim 3, wherein a material of the transmissive part is same as a material of the partition wall part,
the housing further comprises a second shielding part disposed on the partition wall part and having a light transmittance smaller than the light transmittance of the transmissive part,
a material of the second shielding part is same as a material of the first shielding part,
the display device further comprises a circuit board on which the first light emitting part and the second light emitting part are mounted, the circuit board being fixed to the housing,
the circuit board is in contact with a contacting region of the partition wall part,
the second shielding part is not disposed on the contacting region,
the housing further comprises a second diffusion part disposed on the second shielding part and configured to diffuse light,
a material of the first diffusion part is same as a material of the second diffusion part,
the transmissive part defines an outer shape of the housing, and
the light transmittance of the transmissive part is equal to or more than 5% and equal to or less than 80%.
